(19) United States
(12) Patent Application Publication
(10) Pub. No.: US 2012/0007742 A1
(43) Pub. Date: Jan. 12, 2012

(54) CONSUMER ELECTRONICS DEVICE HAVING REPLACEABLE ION WIND FAN

(75) Inventors: Scott L. GOOCH, San Carlos, CA (US); Brian D. Sawyer, Palo Alto, CA (US); Wei-Min Jeff Wang, Palo Alto, CA (US)

(73) Assignee: Ventiva, Inc., Santa Clara, CA (US)

(21) Appl. No.: 13/014,513

(22) Filed: Jan. 26, 2011

Related U.S. Application Data
(60) Provisional application No. 61/362,977, filed on Jul. 9, 2010.

(51) Int. Cl. G08B 21/00; H05K 7/20; H01T 23/00; H01J 13/46

(52) U.S. Cl. 340/584; 315/35; 361/697; 361/231

(57) ABSTRACT

A consumer electronics device can be thermally managed using forced convection. In one embodiment, the present invention includes such a consumer electronics device having a heat sink thermally coupled to a heat source. The device also includes a power supply configured to power an ion wind fan, and an ion wind fan electrically coupled to the power supply. In one embodiment, the electric coupling is temporary using a non-permanent electrical connector, and electrical contact occurs when the ion wind fan is removably retained by a retention mechanism.

### CROSS-REFERENCE TO RELATED APPLICATIONS

This Application claims the priority benefit of U.S. Provisional Patent Application No. 61/362977 filed on Jul. 9, 2010 and entitled “Ion Wind Fan Designs,” which is hereby incorporated by reference in its entirety.

### FIELD OF THE INVENTION

The embodiments of the present invention are related to consumer electronics devices, and in particular to a consumer electronics device containing an ion wind fan.

### BACKGROUND

It is well known that heat can be a problem in many electronics device environments, and that overheating can lead to failure of components such as integrated circuits (e.g. a central processing unit (CPU) of a computer) and other electronic components. Most consumer electronics devices, from LED lighting to computers and entertainment devices, implements some form of thermal management to remove excess heat.

Heat sinks are a common passive tool used for thermal management. Heat sinks use conduction and convection to dissipate heat and thermally manage the heat-producing component. To increase the heat dissipation of a heat sink, a conventional rotary fan or blower fan has been used to move air across the surface of the heat sink, referred to generally as forced convection. Conventional fans have many disadvantages when used in consumer electronics products, such as noise, weight, size, and reliability caused by the failure of moving parts and bearings.

A solid-state fan using ionic wind to move air addresses the disadvantages of conventional fans. However, providing an ion wind fan that meets the requirements of consumer electronics devices presents numerous challenges not addressed by any currently existing ionic wind device. Furthermore, incorporating an ion wind fan into a lighting device, such as an LED light bulb presents further challenges.

### BRIEF DESCRIPTION OF THE DRAWINGS

FIG. 1 is a block diagram illustrating an ion wind fan implemented as part of thermal management of an electronic device;

FIG. 2A is a perspective view of an ion wind fan according to one embodiment of the present invention;

FIG. 2B is a widthwise cross-sectional view of the ion wind fan of FIG. 2A according to one embodiment of the present invention

FIG. 3 is an exploded view of an solid-state light bulb according to one embodiment of the present invention;

FIG. 4 is a perspective view of the light bulb of FIG. 3 according to one embodiment of the present invention;

FIG. 5A is plan view of a heat sink according to another embodiment of the present invention;

FIG. 5B is perspective view of the heat sink of FIG. 5A according to another embodiment of the present invention;

FIG. 6A is a cross-sectional plan view of a solid state light bulb according to one embodiment of the present invention;

FIG. 6B is cross-sectional perspective of the solid state light bulb of FIG. 6A according to another embodiment of the present invention;

FIG. 7A is plan view of another heat sink according to another embodiment of the present invention;

FIG. 7B is perspective view of the heat sink of FIG. 7A according to another embodiment of the present invention;

FIG. 8 is a perspective view of an ion wind fan according to another embodiment of the present invention;

FIG. 9A is a perspective view of a fan cartridge including an ion wind fan according to one embodiment of the present invention;

FIG. 9B is a disassembled perspective view of a fan cartridge including an ion wind fan according to one embodiment of the present invention;

FIG. 10A is a perspective exploded view a fan housing according to one embodiment of the present invention;

FIG. 10B is an disassembled perspective view showing a fan cartridge and a fan housing according to one embodiment of the present invention;

FIG. 11A is a perspective assembled view showing a fan cartridge and a fan housing according to one embodiment of the present invention;

FIG. 11B is a perspective view showing another embodiment of a fan cartridge and a fan housing according to one embodiment of the present invention;

FIG. 12A is a perspective disassembled view showing a removable ion wind fan and a fan housing according to one embodiment of the present invention;

FIG. 12B is a perspective action view showing a removable ion wind fan and a fan housing according to one embodiment of the present invention;

FIG. 12C is a perspective view showing a removable ion wind fan according to one embodiment of the present invention;

FIG. 12D is a perspective view electrical coupling of the removable ion wind fan of FIG. 12C according to one embodiment of the present invention;

FIG. 12E is a perspective exploded view showing a fan housing according to one embodiment of the present invention;

FIG. 12F is a perspective assembled view showing a fan housing according to one embodiment of the present invention;

FIGS. 13A and 13B are perspective views showing a laptop computer having a removable ion wind fan according to one embodiment of the present invention;

FIGS. 14A and 14B are perspective views showing a projector having a removable ion wind fan according to one embodiment of the present invention;

FIG. 15 is a block diagram illustrating a consumer electronics device according to one embodiment of the present invention;

FIG. 16 is a flow diagram illustrating fan authentication according to one embodiment of the present invention; and

FIG. 17 is a flow diagram illustrating user-notification according to one embodiment of the present invention.

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not necessarily be so limited; rather the principles thereof can be extended to other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Ion wind or corona wind generally refers to the gas flow that is established between two electrodes, one sharp and the other blunt, when a high voltage is applied between the electrodes. The air is partially ionized in the region of high electric field near the sharp electrode. The ions that are attracted to the more distant blunt electrode collide with neutral (uncharged) molecules en route to the collector electrode and create a pumping action resulting in air movement. The high voltage sharp electrode is generally referred to as the emitter electrode or corona electrode, and the grounded blunt electrode is generally referred to as the counter electrode, getter electrode, or collector electrode.

The general concept of ion wind—also sometimes referred to as ionic wind and corona wind even though these concepts are not entirely synonymous—has been known for some time. For example, U.S. Pat. No. 4,210,847 to Shannon, et al., dated Jul. 1, 1980, titled “Electric Wind Generator” describes a corona wind device using a needle as the sharp corona electrode and a mesh screen as the blunt collector electrode. The concept of ion wind has been implemented in relatively large- scale air filtration devices, such as the Sharper Image Ionic Breeze.

### Example Ion Wind Fan Thermal Management Solution

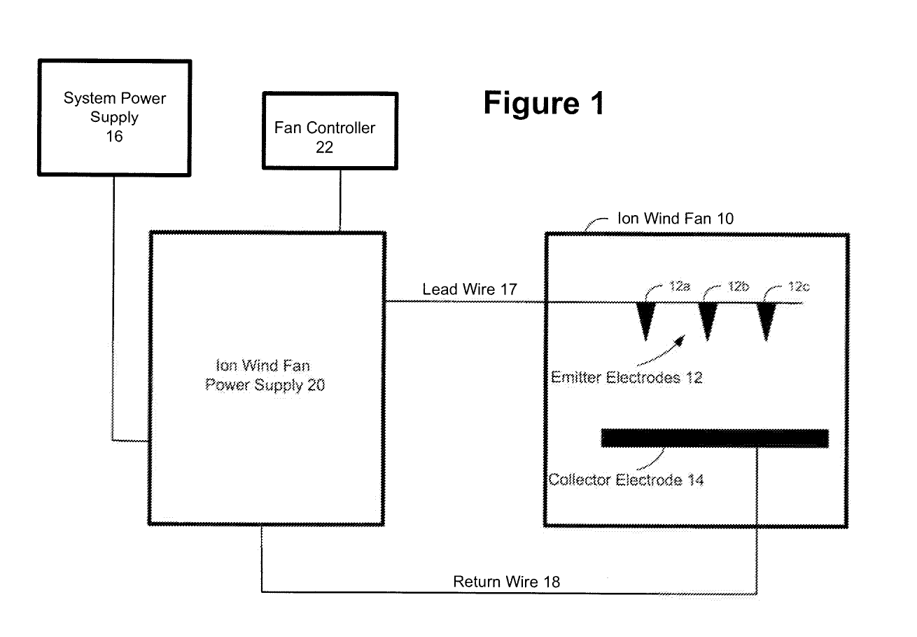

FIG. 1 illustrates an ion wind fan 10 used as part of a thermal management solution for an electronic device. As used in this Application, the descriptive term “ion wind fan,” is used to refer to any electro-aerodynamic pump, electro-hydrodynamic (EHD) pump, EHD thruster, corona wind device, ionic wind device, or any other such device used to move air or other gas. The term “fan” refers to any device that move air or some other gas. The term ion wind fan is meant to distinguish the fan from conventional rotary and blower fans. However, any type of ionic gas movement can be used in an ion wind fan, including, but not limited to corona discharge, dielectric barrier discharge, or any other ion generating technique.

An electronic device may need thermal management for an integrated circuit—such as a chip or a processor—that produces heat, or some other heat source, such as a light emitting diode (LED). Some example systems that can use an ion wind fan for thermal management include computers, laptops, gaming devices, projectors, television sets, set-top boxes, servers, NAS devices, memory devices, LED lighting devices, LED display devices, smart-phones, music players and other mobile devices, and generally any device having a heat source requiring thermal management.

The electronic device can have a system power supply 16 or can receive power directly from the mains AC via a wall outlet, Edison socket, or other outlet type. For example, in the case of a laptop computer, the laptop will have a system power supply such as a battery that provides electric power to the electronic components of the laptop. In the case of a wall-plug device such as a gaming device, television set, or LED lighting solution (lamp or bulb), the system power supply 16 will receive the 110V mains AC (in the U.S.A, 220V in the EU) current from an electrical outlet or socket.

The system power supply 16 for such a plug or screw-in device will also convert the mains AC into the appropriate voltage and type of current needed by the device (e.g., 20-50V DC for an LED lamp). While the system power supply 16 is shown as separate from the IWFPS 20, in some embodiments, one power supply can provide the appropriate voltage to both an ion wind fan 10 and other components of the electronic device. For example, a single driver can be design to drive the LEDs of and LED lamp and an ion wind fan included in the LED lamp.

The electronic device also includes a heat source (not shown), and may also include a passive thermal management element, such as a heat sink (also not shown). To assist in heat transfer, an ion wind fan 10 is provided in the system to help move air across the surface of the heat source or the heat sink, or just to generally circulate air (or some other gas) inside the device. In prior art systems, conventional rotary fans with rotating fan blades have been used for this purpose.

As discussed above, the ion wind fan 10 operates by creating a high electric field around one or more emitter electrodes 12 resulting in the generation of ions, which are then attracted to a collector electrode 14. In FIG. 1, the emitter electrodes 12 are represented as triangles as an illustration that they are generally “sharp” electrodes. However, in a real-world ion wind fan 10, the emitter electrodes 12 can be implemented as wires, shims, blades, pins, and numerous other geometries. Furthermore, while the ion wind fan 10 in FIG. 1 has three emitter electrodes (12a, 12b, 12c), the various embodiments of the present invention described herein can be implemented in conjunction with ion wind fans having any number of emitter electrodes 12.

Similarly, the collector electrode 14 is shown simply as a plate in FIG. 1. However, a real-world collector electrode 14 can have various shapes and will generally include openings to allow the passage of air. The collector electrode 14 can also be implemented as multiple collector electrode members (e.g., rods, washers) held at substantially the same potential. Furthermore, in a real world ion wind fan 10, the emitter electrodes 12 and the collector electrode 14 would be disposed on a dielectric chassis—sometimes referred to as an isolator element—that has also been omitted from FIG. 1 for simplicity and ease of understanding.

To create the high electric field necessary for ion generation, the ion wind fan 10 is connected to an ion wind power supply 20. The ion wind power supply 20 is a high-voltage power supply that can apply a high voltage potential across the emitter electrodes 12 and the collector electrode 14. The ion wind fan power supply 20 (hereinafter sometimes referred to as “IWFPS”) is electrically coupled to and receives electrical power from the system power supply 16. Usually for electronic devices, the system power supply 16 provides low-voltage direct current (DC) power. For example, a laptop computer system power supply would likely output approximately 5-12V DC, while the power supply for an LED light fixture would likely output approximately 20-70V DC.

The high voltage DC generated by the IWFPS 20 is then electrically coupled to the emitter electrodes 12 of the ion wind fan 10 via a lead wire 17. The collector electrode 14 is connected back to the IWFPS 20 via return/ground wire 18, to ground the collector electrode 14 thereby creating a high voltage potential across the emitters 12 and the collector 14 electrodes. The return wire 18 can be connected to a system, local, or absolute high-voltage ground using conventional techniques.

While the system shown in and described with reference to FIG. 1 uses a positive DC voltage to generate ions, ion wind can be created using AC voltage, or by connecting the emitters 12 to the negative terminal of the IWFPS 20 resulting in a “negative” corona wind. Embodiments of the present invention are not limited to positive DC voltage ion wind. Furthermore, while the IWFPS 20 is shown to receive power from a system power supply 30, in other embodiment, the IWFPS 20 can receive power directly from an outlet.

The IWFPS 20 may include other components. Furthermore, in some embodiments, some of the components listed above may be omitted or replaced by similar or equivalent circuits. For example, the IWFPS 20 is described only as an example. Many different kinds and types of power supplies can be used as the IWFPS 20, including power supplies that do not have a transformers or other components shown in FIG. 1. The components described need not be physically separate, and may be combined on a single printed circuit board (PCB).

As described partially above, ion wind is generated by the ion wind fan 10 by applying a high voltage potential across the emitter 12 and collector 14 electrodes. This creates a strong electric field around the emitter electrodes 12, strong enough to ionize the air in the vicinity of the emitter electrodes 12, in effect creating a plasma region. The ions are attracted to collector electrode 12, and as they move in air gap along the electric field lines, the ions bump into neutral air molecules, creating airflow. On a real world collector electrode 14, air passage openings (not shown) allow the airflow to pass through the collector 14 thus creating an ion wind fan.

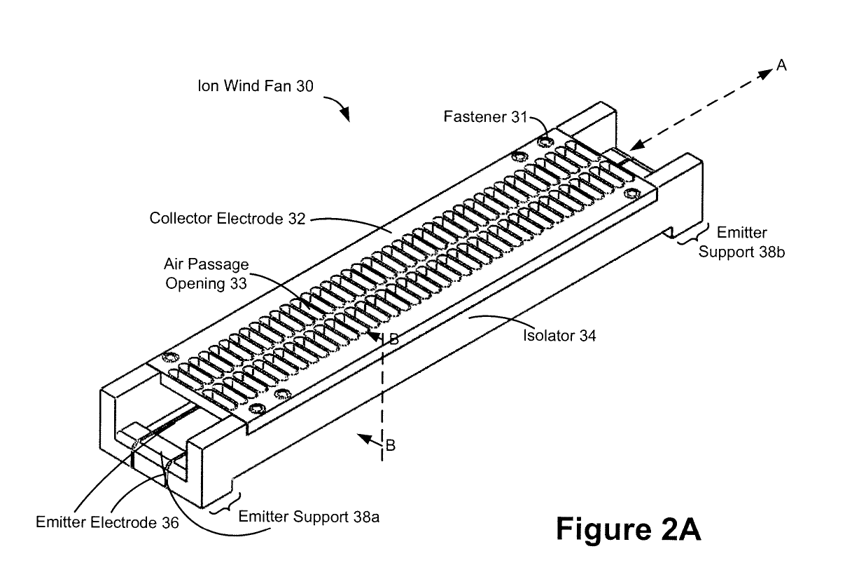

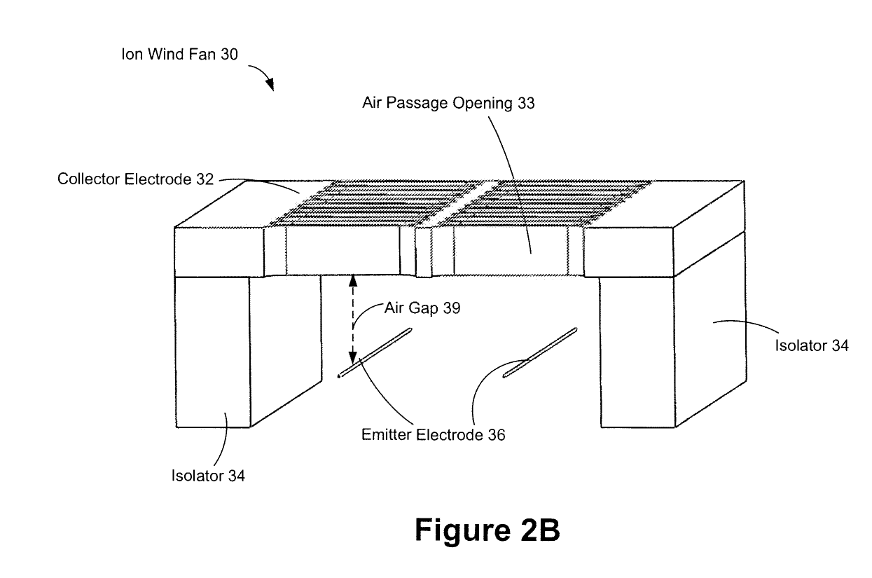

An example of such an ion wind fan is now described with reference to FIGS. 2A and 2B. FIG. 2A is a perspective view of an example ion wind fan 30. The ion wind fan 30 includes a collector electrode 32 having air passage openings 33 to allow airflow. This example ion wind fan 30 has two emitter electrodes 36 implemented as wires, thus implementing what is sometimes referred to as a “wire-to-plane” configuration.

The collector electrode 32 and the emitter electrodes 36 are both supported by an isolator 34. The isolator is made of a dielectric material, such as plastic, ceramic, and the like. The “isolator” component is thusly named as it functions to electrically isolate the emitter electrodes 36 from the collector electrode 32, and to physically support these electrodes. As such the isolator also can establish the spatial relationship between the electrodes, sometimes referred to under the rubric of electrode geometry. The isolator 34 can be made from one integral piece—as shown in FIG. 2A—or it can be made of multiple parts and pieces.

In the embodiment shown in FIG. 2A, the collector electrode is attached to the isolator using a fastener 31. The fastener 31 in FIG. 2 is a stake, but any other attachment method can be used, including but not limited to screws, hooks, glue, and so on. Similarly, the particular method of attachment of the emitter electrodes 36 is not essential to the embodiments of the present invention. The emitter electrodes 36 can be glued, staked, screwed, tied, held by friction, or attached in any other way to the isolator 34.

The ion wind fan 30—in the embodiment shown in FIG. 2A—is substantially rectangular in top view. The longitudinal axis of the ion wind fan 30 is denoted with the dotted arrow labeled “A.” The ion wind fan 30 has two ends opposite each other along the longitudinal axis. The emitter electrodes 36 are suspended between the two ends of the ion wind fan 30.

In one embodiment, the emitter electrodes 36 are supported at the ends of the ion wind fan 30 by an emitter support 38 portion of the isolator 34. The emitter support 38a at the left end of the ion wind fan 30 is most visible in FIG. 2A. The emitter support 38a is a portion of the isolator that physically supports the emitter electrodes 36. In one embodiment, the emitter electrodes 36 are suspended (in tension) between the two emitter supports 38 at the two ends of the ion wind fan 30.

In the embodiment shown in FIG. 2A, the isolator 34 has two elongated members oriented along the longitudinal direction that support the collector electrode 32, and the two elongated members are held joined by two cross-members that support the emitter electrodes 36. In one embodiment, these cross-members are oriented perpendicular to the elongated members (and thus the longitudinal axis). In FIG. 2A, these cross-members make up the emitter supports 38.

Thus, while in one embodiment the emitter support 38a is a substantially rectangular solid portion of the isolator 34 that connects the two elongated side portions of the isolator 34, in other embodiments the emitter supports 38 can have many other shapes and orientations. For example, a part of the center portion of the emitter support 38a between the emitter electrodes 36 could be cut away without substantially affecting the function of the emitter support 38a.

The emitter support 38a is shown as extending to the end of the ion wind fan 30. However, in other embodiments, the emitter support 38a can end before the end of the ion wind fan 30. The emitter support 38a is also shown as having a curved section at its outside edge to smooth out the 90 degree bend in the wire emitter electrodes 36. This is an optional feature not related to the embodiments of the present invention described herein.

Indeed, the actual attachment of the emitter electrodes 36 to either the emitter support 38 or some other portion of the isolator 34 is not material to the embodiments of the present invention, and therefore will not be discussed in much detail for simplicity and ease of understanding. The emitter electrodes 36 are shown as extending downward from the left end of the ion wind fan 30 and they are connected to the power supply via some wire or bus, as is the collector electrode 32. The emitter supports 38 need not have any particular shape of contact with the emitter electrodes 36. The emitter supports 38 are the portions of the isolator 34 that define the physical spatial relationship between the emitter electrodes 34 and other components of the ion wind fan 30. How exactly the emitter supports 38 are in contact with the emitter electrodes 36 (grooves, stakes, friction, posts, welding, epoxy) are not germane to the embodiments of the present invention.

FIG. 2B further illustrates the example ion wind fan 30 shown in FIG. 2A. FIG. 2B is a perspective cross sectional view of the ion wind fan 30 along the line B-B shown in FIG. 2A. The emitter electrodes 36 are suspended in air, and held a substantially constant air gap 39 distance away from the collector electrode 32.

Though wire sag and other emitter irregularities will create some variance, in one embodiment the air gap 39 between the emitter electrodes 36 and the bottom plane of the collector electrode 32 is substantially constant (within a 5% variation). In other embodiments, the air gap 39 can be more variable. The size of the air gap 39 is dependent on the spatial relationship between the electrodes established by the emitter supports 38 (which are not visible in FIG. 2B).

### Solid-State Light Bulb

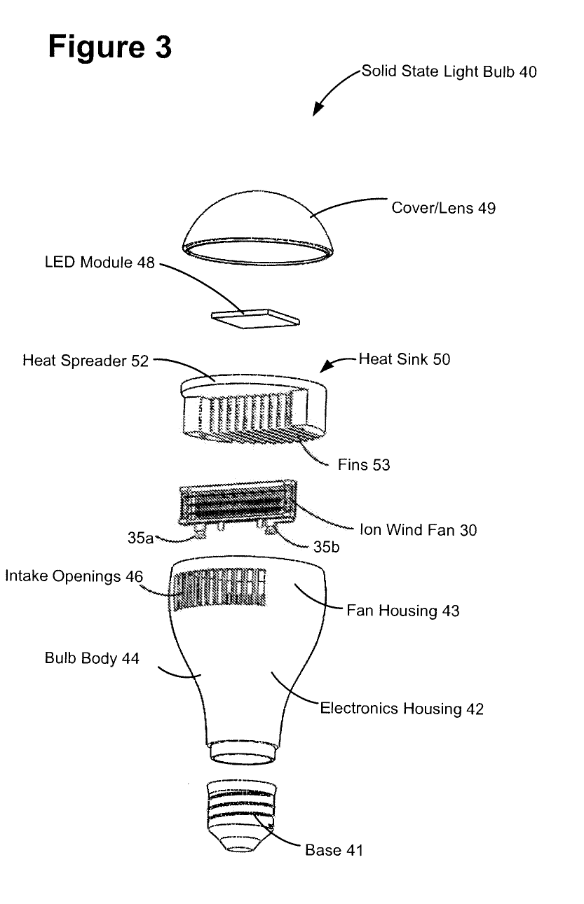

FIG. 3 shows some components of a solid-state (LED) light bulb 40 in an exploded view. Many components—such as electronics and electrical connections—have been omitted for simplicity, ease of understanding, and in order not to obscure the various embodiments of the invention. The light bulb 40 includes a base 41, which can be an screw-type base designed to work with an Edison-socket or another type of electrical connector for the bulb 40. The bulb 40 further includes a bulb body 44, which is roughly divided into the electronics housing 42 and the fan housing 43.

In one embodiment, the bulb body 44 is made of a dielectric material, such as plastic, thermoplastic, ceramic, liquid crystal polymer, or any other known insulator. In one embodiment, the bulb body 44 is single unitary piece of injection-molded plastic, but it can be assembled from multiple pieces in other embodiments. In other embodiments, only a portion of the bulb body 44 is made of the dielectric material.

The fan housing 43—which is the portion of the bulb body 44 that houses the ion wind fan 30—includes a set of intake openings 46 and a set of exhaust openings that is not visible in FIG. 3 because of the orientation of the bulb 40. The electronics housing 42 has a hollow cavity to house various electronics components, such as an LED power supply and driver, and the ion wind fan power supply. In one embodiment, this hollow cavity is then electrically isolated from the fan housing 43 with a dielectric cover (not shown), except for the necessary electrical connections.

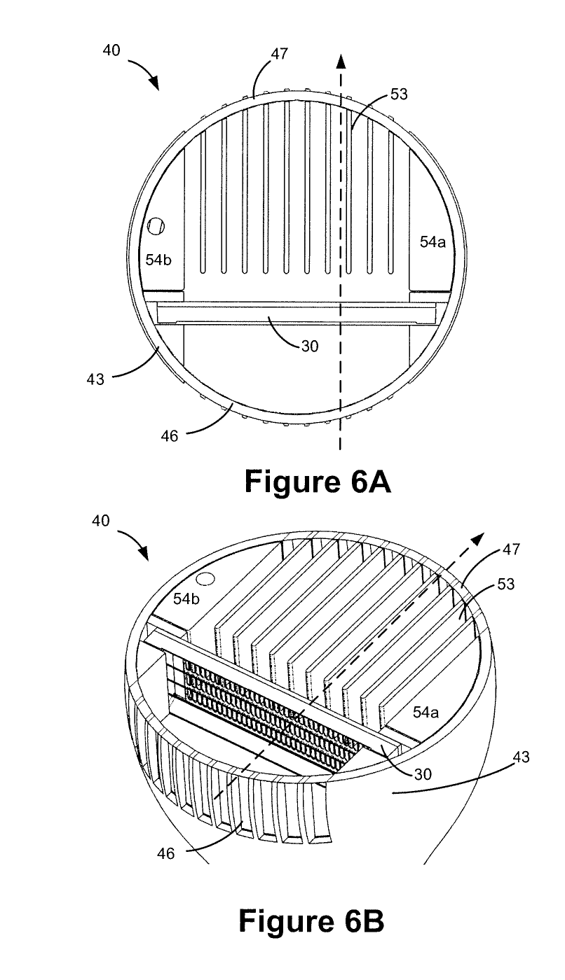

The ion wind fan 30 is located inside a cavity formed by the fan housing 43. In one embodiment, as shown in FIGS. 6A and 6B, the ion wind fan 30 is positioned along a chord of the circular cross-section of the fan housing 43, where the chord is not the widest portion having the largest diameter. The ion wind fan 30 is positioned to generate an airflow from the intake openings 46 towards to exhaust openings 47, thereby causing a current of air through fan housing 43.

In one embodiment, the bulb 40 further includes a heat sink 50. As shown in FIG. 3, in one embodiment, the heat sink 50 has a flat, round-shaped heat spreader 52 portion. Since the cross-section of this bulb 40 is round, a round shaped heat spreader 52 maximizes the available area for heat dissipation. However, in other embodiment, other shapes, such as square, octagonal, or other such shapes can be used for the heat spreader 52.

In one embodiment, an LED module 48 is mounted on the top portion of the heat spreader 52, while a plurality of fins 53 extend from an opposite surface of the heat spreader 52, thus creating heat sink 50. These surfaces may sometimes be referred to as the proximate (to the heat source) and distal surface, respectively. In the embodiment shown, the heat spreader 52 has substantially flat proximal and distal surfaces. However, in other embodiments, the proximal surface of the heat spreader 52 may be domed, pyramid-shaped, or having some other contour. The distal surface may also not be flat in other embodiments. The heat sink 50 can be manufactured as a single cast piece of metal, but other manufacturing techniques can also be used. In yet other embodiments, the heat spreader 52 and the fins 53 can be assembled from separate subcomponents (e.g. by welding on each fin or a fin stack).

As set forth above, LED module 48—or other solid-state light devices—are mounted on or thermally coupled to the proximal surface of the heat spreader 52. The bulb also includes a cover/lens/diffuser 49. The cover 49 is transparent or translucent, and may act as a lens or other optics. The cover/lens 49 and the proximal surface of the heat spreader 52 define an optics cavity, where the optical components (such as LED module 48) are housed. The bulb body 44 and the cover 49 define the shape as well as the inside/interior and outside/exterior of the bulb 40.

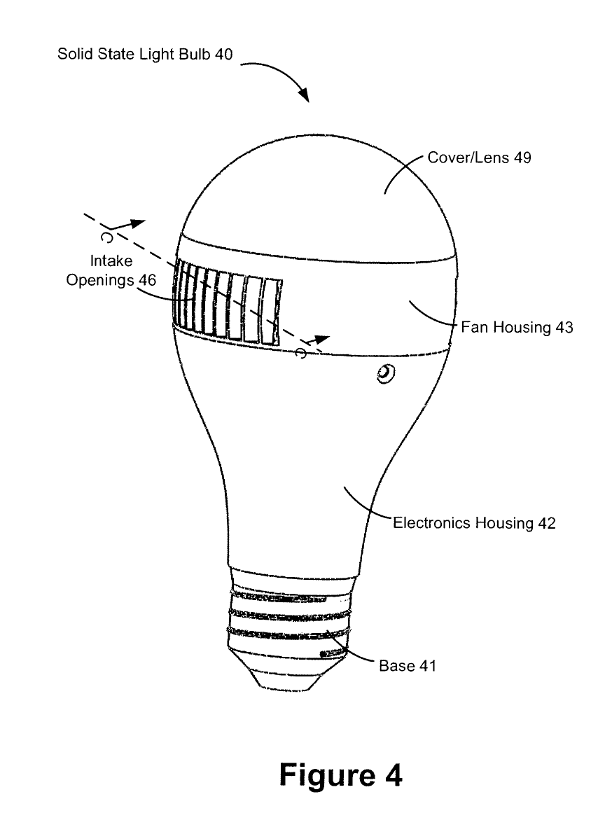

FIG. 4 shows the assembled view of the bulb 40 that is shown in exploded view in FIG. 3. One aspect of this embodiment of the present invention, is that, when assembled (as shown in FIG. 4) the metallic heat sink 50 is not exposed to the outside of the bulb 40. During ordinary handling, a person could touch the cover/lens 58 or the bulb body 44, but the heat sink 50 is fully contained inside the bulb 40.

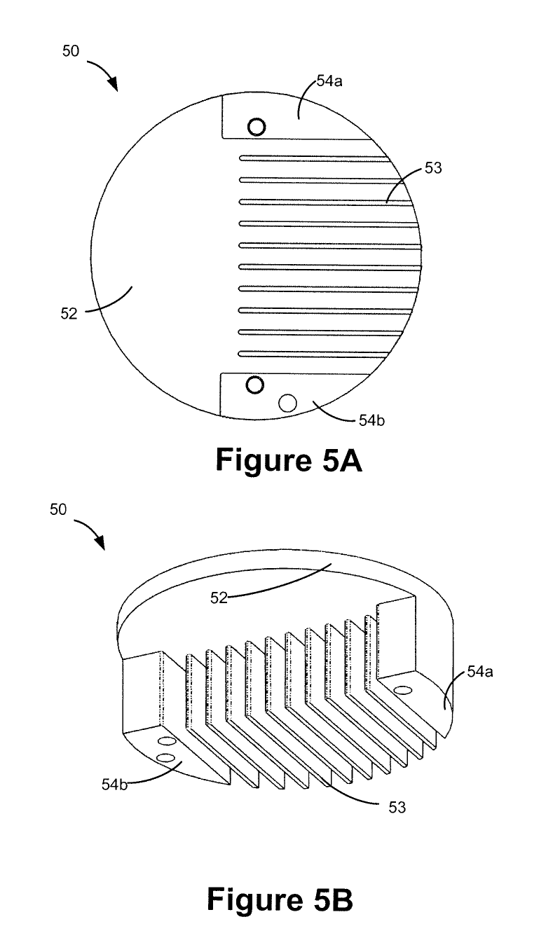

FIG. 5A is a plan view of the heat sink 50 as sighted from the base 41 toward the lens 49. Visible is the distal side of the heat spreader 52 and the fins 53 protruding therefrom. The pitch, thickness, and number of fins can vary in different embodiments. As shown in FIG. 5A, the fins 53 have variable lengths and form air passage channels having variable lengths. The fins in the middle are longer due to the circular shape of the heat spreader 52.

In one embodiment, also extending from the heat spreader 52 are two rounded side-fins 54 which are thicker than the fins 53 and have an outside edge that conforms to the circular shape of the heat spreader 52. In one embodiment, the side-fins 54 are solid because the ion wind fan 30 does not generate airflow in the portion of the heat spreader 52 that they occupy. FIG. 5B is a perspective view of one embodiment of the heat sink 50 shown in FIG. 5A, further illustrating the air passage channels formed by the fins 53. The dimensions of the heat sink 50 are specific to each embodiment, but in one case, the diameter of the heat spreader 52 is the approximate diameter of an A-type light bulb, such as an A-19 bulb.

FIGS. 6A and 6B are cross-sectional views of the bulb 40 shown in FIGS. 3 and 4, the cross-section taken along the C-C line shown in FIG. 4. The cross-section is basically perpendicular to the longitudinal axis of the bulb 40 (that extends from the base 41 to the top of the cover 49) and taken around the air intake openings 46. Visible in FIGS. 6A and 6B are the fan housing 43 having intake 46 and exhaust 47 openings, the fins 53 and side-fins 54 of the heat sink 50, and the ion wind fan 30. Also visible, is a fan support structure that can be a part of the fan 30, the fan housing 43, or a separate structure. The dotted arrow indicates the approximate direction of the airflow generated by the ion wind fan 30.

In the embodiment shown, the exhaust openings 47 of the fan housing 43 are sized so that they substantially align with the air passage channels between the fins 53 of the heat sink 50. For example, as shown in FIG. 6, the fins 53 define eleven (11) air passage channels. In the embodiment shown, there are also eleven exhaust openings 47 on the fan housing 43. Thus in one embodiment, the exhaust openings 47 extend the air passage channels, so that the walls of the channels are defined by the fins 53 for most of the length of the air passage channels, but are defined by the exhaust openings 47 for the final portion of the air passage channel where air exits the bulb 40. Thus the walls of the channels are metallic in general, but become dielectric at the edge of the bulb 40.

In other embodiments, the exhaust openings 47 need not align or mate with the air passage channels of the heat sink 50. For example, the exhaust openings 47 may be perpendicular to the shape of the air passage channels defined by the fins 53. In yet other embodiments, the exhaust openings 47 can be round, oval, or any other shape. Similarly, the air passage channels defined by the fins 53 may have shapes other than rectangular as well.

One aspect of the embodiment shown in FIG. 6—as well as FIGS. 3-5—is that there is no obstruction to the airflow upstream of the ion wind fan 30. In other words, there are no fins or other structures between the intake openings 46 and the ion wind fan 30. To optimize this design, the ion wind fan 30 is not placed across the diameter of the fan housing 43 to maximize the possible length of the ion wind fan 30. Instead, the ion wind fan 30 is positioned along a chord of the circle defined by the cross-section of the fan housing 43. In one embodiment, the length of the chord is between 50-90 percent of the length of the diameter of the circular cross-section.

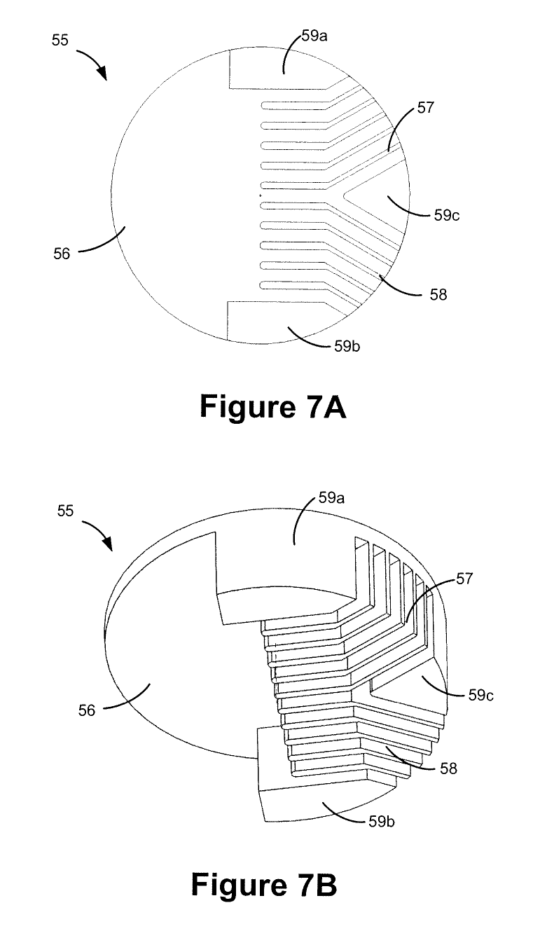

The heat sink 50 shown in FIGS. 5 and 6 is just one embodiment of a heat sink having only downstream fins that can be used with the various embodiments of the present invention. For example, FIGS. 7A and 7B illustrate a heat sink 55 having angled air-passage channels. The heat sink 55 has two solid side-fins 59a,b and a solid middle fin 59c that has an approximately wedge shape. The heat sink also has a set of fins 57 that direct the airflow right of the middle fin 59c and another set of fins 58 that direct the air left of the middle fin 59c.

As shown in FIG. 7, the fins 57,58 have an angled bend that angle left and right respectively. However, other embodiments can use curved fins to define curving instead of angular air-passage channels. Various other fin stack shapes are possible, and the number of fins, the fin pitch, and fin thickness are all implementation-specific.

While in the embodiments shown and described above, the LEDs (or other solid-state light devices) are mounted to the heat sink 50,55, in other embodiments the thermal coupling can be accomplished in other ways. For example, U.S. patent application Ser. No. 12/782,602 entitled “Solid-State Light Bulb Having an Ion Wind Fan and a Heat Pipe,” filed on May 18, 2010 and having the same assignee as the present Application—which application is herein incorporated fully by reference—describes a solid-state light bulb where the LEDs are coupled to heat sink fins via one or more heat pipes. The fins of such an embodiment can be perpendicular to the fins of heat sink 50 as described above. However, such a heat sink and heat pipe can be electrically isolated using the same or similar techniques and configurations described above. The intake and exhaust openings may change in orientation to mate with the air passage channels, or they may have any other shape where such mating is not implemented.

Lighting Device with Replaceable Ion Wind Fan

LED light bulbs and light devices are marketed as being able to achieve 10,000-50,000 hours of operation, and may be able to operate even longer with future technological gains. While the reliability of ion wind fan technology is promising and superior to rotary fan reliability on the LED lighting scale, there is a possibility that ion wind fan failure will occur prior to LED failure. According to various embodiments of the present invention, an LED light bulb has a replicable ion wind fan that eliminates reliability concerns of ion wind fan technology.

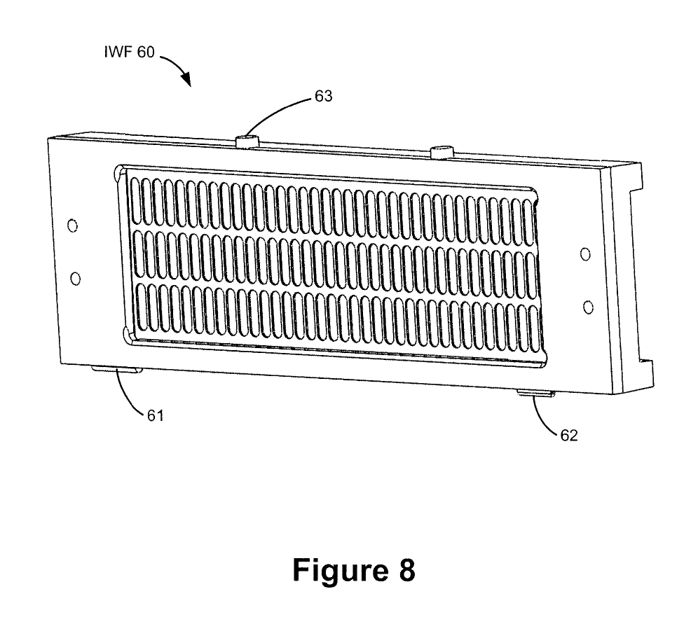

FIG. 8 is a perspective upstream view of an ion wind fan 60. The ion wind fan 60 is similar to the ion wind fan 30 shown in FIG. 3 and to those embodiments described in U.S. Provisional Patent Application No. 61/362977 filed on Jul. 9, 2010 and entitled “Ion Wind Fan Designs,” which is hereby incorporated by reference in its entirety. However, instead of having rigid contacts (35a,35b) designed for permanent connection to an IWFPS 20, the ion wind fan 60 has a collector electrode spring contact 61 and an emitter electrode spring contact 62. Various types of spring and spring-style contacts can be used.

In one embodiment, the collector spring contact 61 is a hook or loop structure capable of some mechanical deflection. The contact 61 can be integrally formed with the collector electrode or can be electrically coupled to the collector electrode. In one embodiment, the contact is stamped and formed from the same monolithic metal piece from which the collector is formed, and is thus integrally formed with the collector electrode. The collector electrode is then insert-molded into the body of the isolator when the isolator is being created, such that the contact 61 protrudes from the isolator as shown in FIG. 8.

The emitter spring contact 62 can be formed and designed similarly to the collector contact 61. In one embodiment, the emitter electrodes are attached to the isolator by being welded to an emitter bus plate that is insert-molded into the isolator, though other attachment techniques can be used. The emitter bus plate includes a plate-like surface that protrudes from the isolator in the area where emitter attachment is desired, and is used to provide electrical connection from the IWFPS to the emitter electrodes.

In such an embodiment, the emitter contact 62 can be formed—e.g. stamped—from the same metal component that makes up the emitter bus plate, which electrically connects the emitter electrodes to the IWFPS 20. Once again, during insert-molding, the bus plate is positioned so that the emitter spring contact 62 is positioned as shown in FIG. 8. As explained above, various spring-contact designs can be used for these contacts 61, 62. Also shown in FIG. 8 are locations posts 63, which are protrusions from the isolator that locate the ion wind fan 60, as described further below.

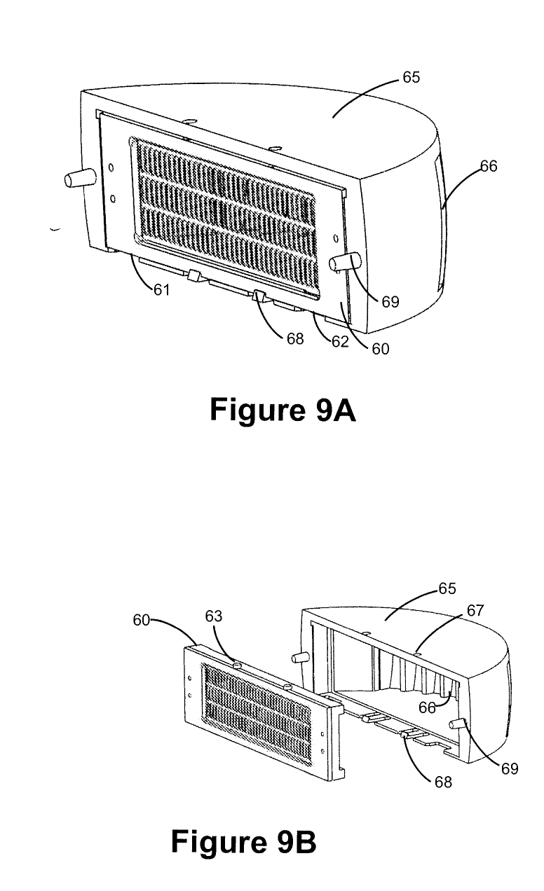

FIGS. 9A and 9B illustrate a removable ion wind fan cartridge 65. For the LED light bulb application shown in FIG. 9, the shape of the cartridge 65 is the approximate shape of the cross section of the LED bulb 40 upstream of the ion wind fan. As can be seen in FIG. 9B, two spring-hooks 68 in combination with two location holes that receive the location posts 63 retain the ion wind fan 60 inside the cartridge 65.

In one embodiment, the fan cartridge 65 has a plurality of air intake openings 66 and an open area that can be thought of as an air exhaust opening that receives the ion wind fan 30. While in the embodiment shown, the ion wind fan 60 is situated in the cartridge 65 so that the openings of the collector electrode become the exhaust openings of the cartridge 65, the ion wind fan 60 could be situated deeper within the cavity of the cartridge 65.

In the embodiment shown, the ion wind fan 60 is mounted in the cartridge 65 so that the collector electrode faces outward. One advantage of this is that the fragile emitter electrodes—in this embodiment they are thin wire electrodes—are protected during handling when replacing the ion wind fan 60. In fact, in some embodiments, the ion wind fan 60 can be non-removably mounted inside the cartridge 65 using screws, glue, or other appropriate permanent attachment means.

As used in this Application, the term “removable attachment,” “removably attached” and the like refer to attachment methods and techniques that anticipate and enable detachment and attachment by end users of consumer electronics products who are not trained electronics professionals. Thus, if a fan 60 is non-removably attached to the cartridge using screws, while the screws may be unscrewed, such action is not anticipated or required during normal use of the light bulb by its end user. Common examples or non-permanent contacts and removable attachments are found in many socket connections, for example the connection between an Ethernet cable and Ethernet port.

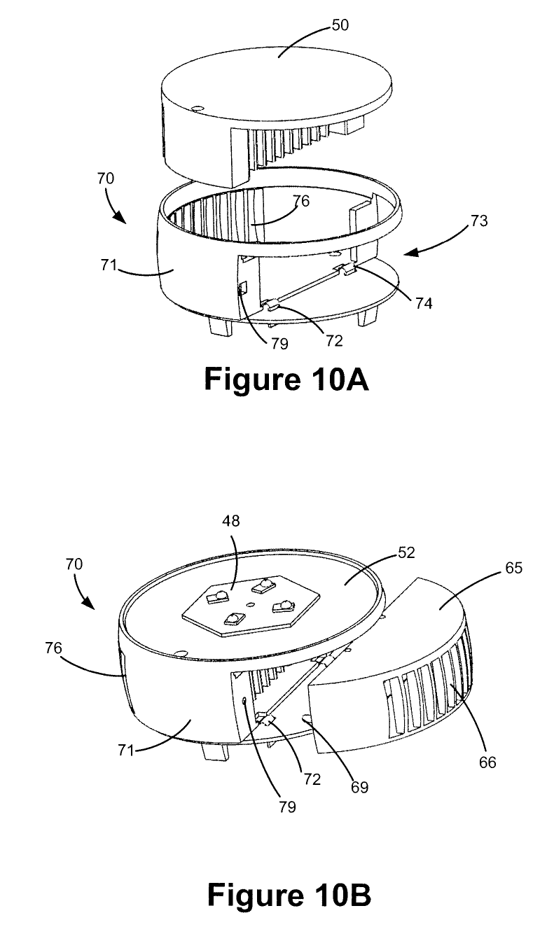

The fan cartridge 65 shown also includes two retention posts 69 to be described further below. FIGS. 10A and 10B illustrate the insertion, removal, and retention of the fan cartridge 65 according to one embodiment of the present invention. The LED light bulb 70 has a fan housing 71 that includes air exhaust openings 76 and a cartridge insertion area 72. A heat sink, such as heat sink 50 or heat sink 60, is received by the fan housing 71 in a similar fashion as described with reference to FIGS. 6A and 6B, and an LED module 48 is thermally coupled to the heat sink, as described with reference to FIG. 3.

The fan housing 71 includes two non-permanent electrical connectors 72, 73. Non-permanent electrical connector 73 is connected to the low side of the IWFPS 20 and electrical connector 72 is connected to the high side of the IWFPS 20. When the cartridge 65 is inserted into the fan housing 71 as shown in FIG. 10B, the non-permanent electrical connectors 72,73 engage the contacts 62, 61 respectively, thus forming a non-permanent electrical connection that connects the ion wind fan 60 to the IWFPS 20. In a negative corona embodiment, the connectors or the contacts can be connected to the emitters and the collector is a reverse fashion.

In FIG. 10B, the retention posts 69 of the fan cartridge 65 engage two retention openings 79 to locate and retain the cartridge 65 in position within the fan housing 71. In other embodiments, various other retention mechanisms can be used for this purpose, such as various latch and hook systems, springs, loops, ratchets, snapping mechanisms, or any other known non-permanent removable retention mechanism. In one embodiment, the retention mechanism is non-permanent to enable a user/owner of the light bulb 70 to remove the fan cartridge 65 (thereby removing the ion wind fan), and to insert a new fan cartridge 65 containing a new ion wind fan 60. FIG. 10C shows the fan housing 71 with the fan cartridge 65 fully inserted and locked in by the retention mechanism (69, 79).

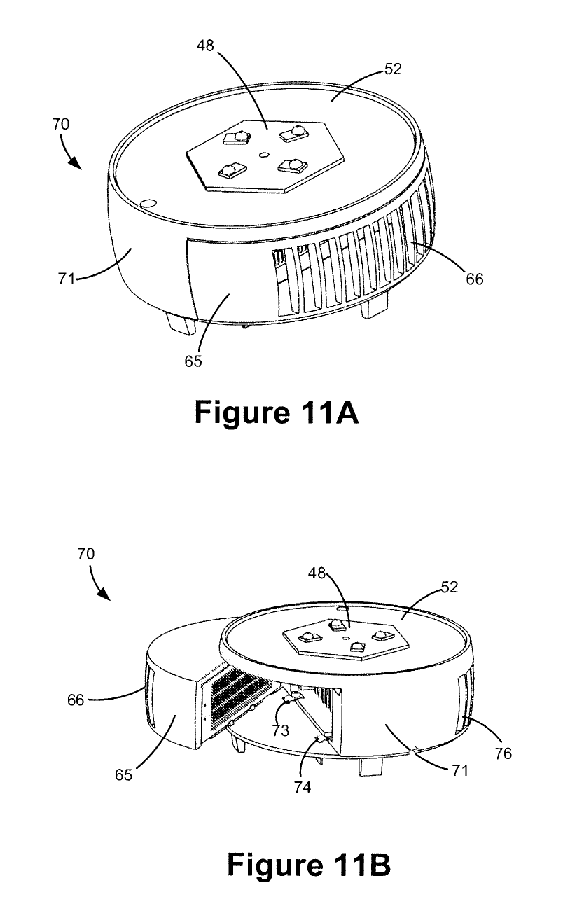

FIG. 11 shows another fan cartridge 65 attachment system, in which the fan cartridge 65 swivels. Such a system enables the swapping of ion wind fans 60 in the cartridge 65 without fully removing the cartridge 65 from the fan housing 71. While the ion wind fan has been described as blowing air from the cavity of the cartridge 65 into the fan housing 71, in other embodiments, the ion wind fan can be turned around to suck air from the fan housing 71 and blow it into the fan cartridge 65.

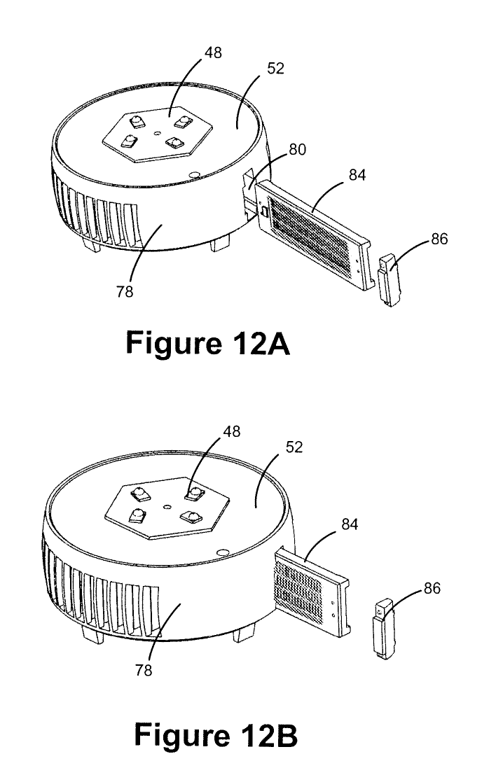

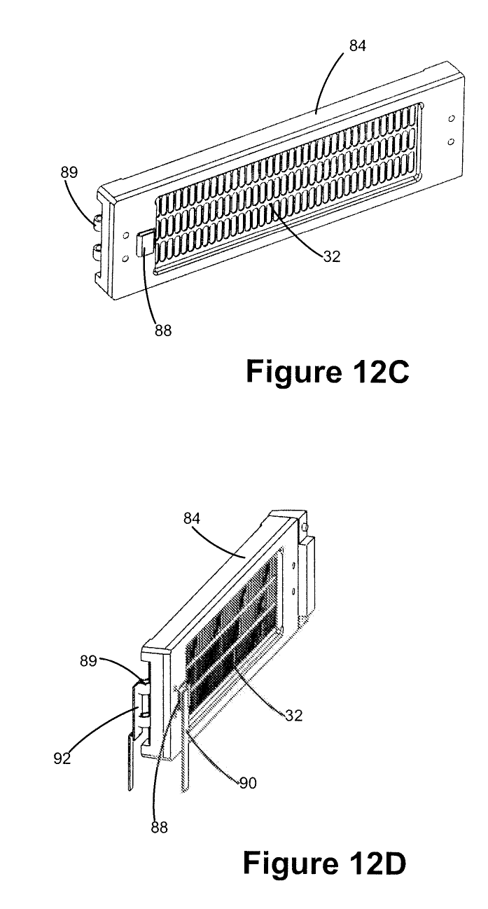

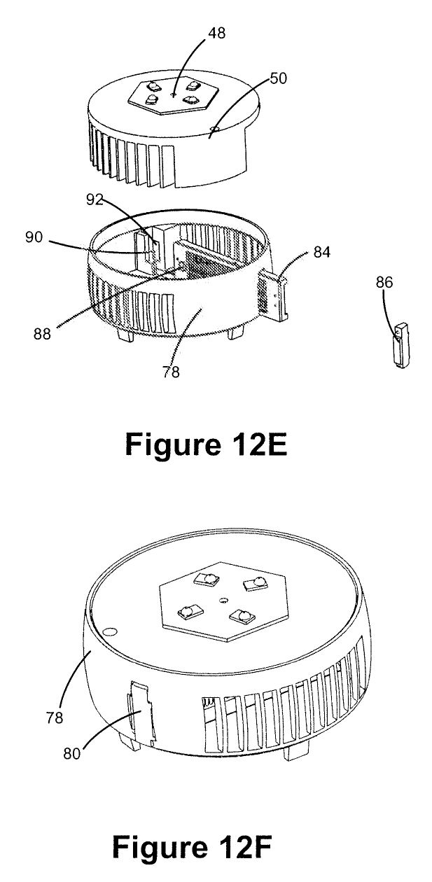

Another embodiment of the present invention is now described with reference to FIGS. 12A-F. FIG. 12 illustrates one embodiment of having a replaceable ion wind fan without using a fan cartridge. FIG. 12A once again shown the fan housing 78 portion of an LED light bulb. As previously, the LED light bulb includes the heat sink 52 on which the LED module 48 is thermally mounted. For other electronics devices, the LED module 48 could be replaced by another generic heat source, such as a processor or other electronics components.

The fan housing 78 has a fan opening 80 that has a shape approximating the cross-section of the ion wind fan 84 for the insertion and removal of the ion wind fan 84. Thus, the ion wind fan 84 can be slidably inserted and removed from the fan housing 78 via the opening 80, as shown in FIGS. 12A and 12B.

In one embodiment, a locking cap 86 having some form of retention mechanism (such as a tab that can snap into place) is used to retain the ion wind fan 84 inside the fan housing 78. In another embodiment, the locking cap 86 is formed integrally with the ion wind fan 84. For example, the cap 86 can be a portion of the isolator 34 of the ion wind fan 84 that is formed when the isolator 34 is injection-molded.

FIGS. 12C and 12D illustrate one embodiment of a non-permanent electrical connection between the ion wind fan 84 and the power supply 20. In the embodiment shown in FIG. 12C, the ion wind fan 84 has a collector contact pad 88 that faces the downstream side of the ion wind fan 84, that is, the side that the collector electrode 32 faces. The collector contact pad 88 can be formed from the same piece of stamped metal as the collector electrode 32.

In one embodiment, the ion wind fan 84 also has two emitter contact bumps 89 that protrude from the emitter bus plate, as shown in FIG. 12C. As shown in FIG. 12C, the emitter contact bumps (or hoops) 89 protrude from the upstream side of the ion wind fan 84. In other embodiments, any number—including one—of emitter contact bumps 89 could be used instead of two.

FIG. 12D shows a non-permanent collector connector 90 that makes removable electrical contact with the collector contact pad 88, and a non-permanent emitter connector 92 that makes removable electrical contact with the emitter contact bumps 89. In this embodiment, both removable electrical contacts 90, 92 have some give and flexibility, so that they recede slightly when an ion wind fan 84 is inserted between the two electrodes, and they spring back with enough pressure to maintain a good non-permanent electrical connection. In one embodiment, the collector contact 90 is electrically coupled to the low side of the power supply while emitter contact 92 is electrically coupled to the high side of the power supply 20, but this can be reversed in other embodiments where negative corona discharge is used by the ion wind fan.

FIG. 12E is an exploded view of the fan housing 12E showing a partially inserted ion wind fan 82. As shown in FIG. 12E, the non-permanent electrical contacts 90, 92 engage the contact pads 88, 89 on the end of the ion wind fan 84 that is opposite to the fan opening 80. However, in other embodiment, the electrical connections can be made on the same side as the opening 80. FIG. 12F shows a fully assembled fan housing 78 with an ion wind fan 84 fully inserted and engaged by the electrical connections via the fan opening 80.

Consumer Electronics Device with Replaceable Ion Wind Fan

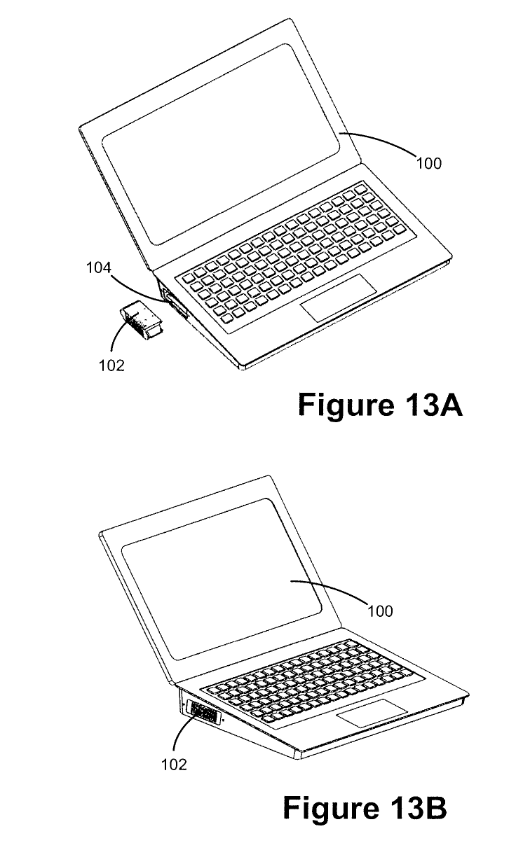

While the previous embodiments have been mostly discussed in the context of an LED or solid-state light bulb being thermally managed, in part, using an ion wind fan that is replaceable by the end consumer, the concepts and designs shown and described with reference to FIGS. 1-12 can be used and adapted to work with other types of consumer electronics devices. For example, FIGS. 13A and 13B show the replaceable ion wind fan concept implemented in a laptop computer 100.

A fan cartridge 102—that can be substantially identical to cartridge 65 except for form factor—can be inserted into an opening 104 on the chassis of the laptop computer 100. FIG. 13A shows the cartridge 102 prior to insertion, and FIG. 13B illustrates the installed cartridge 102. The non-permanent electrical connections can be implemented in any of the ways described above, as can the cartridge retention mechanism.

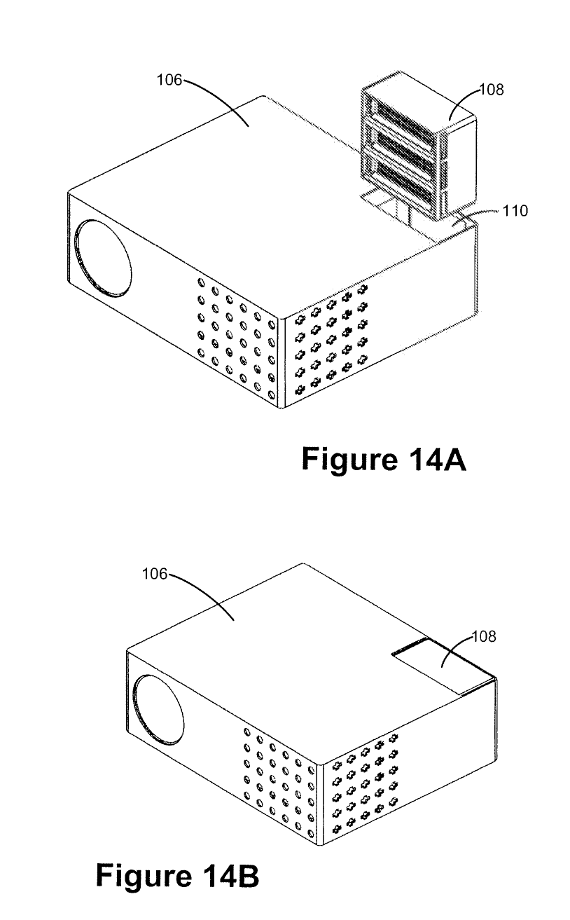

Another embodiment shown in FIGS. 14A and 14B is a projector 106. A multiple fan cartridge 108—as shown holding three ion wind fans—can be inserted into an opening 110 on the chassis of the projector 106. FIG. 14A shows the cartridge 108 prior to insertion, and FIG. 14B illustrates the installed cartridge 108. The non-permanent electrical connections can be implemented in any of the ways described above, as can the cartridge retention mechanism.

The multiple fan cartridge 108 being designed for three fans is only one example, cartridges can be designed to hold any number of fans, and ion wind fans can be designed to adept to the form factor of various cartridges. However, one advantage for using a multi-fan cartridge is that existing ion wind fan designs can be used to generate more airflow without the need to design a larger ion wind fan.

One difference between the cartridges 102 and 108 and the cartridge 65 (as shown) is that cartridge 65 (as shown) is configured to blow air into the electronics device (1ED light bulb), while cartridges 102 and 108 are configured to suck air out of the laptop 100 and the projector 106 respectively. However, as mentioned above, cartridge 65 can be altered to provide reverse airflow by simply changing the orientation of the ion wind fan 60 in the cartridge 65.

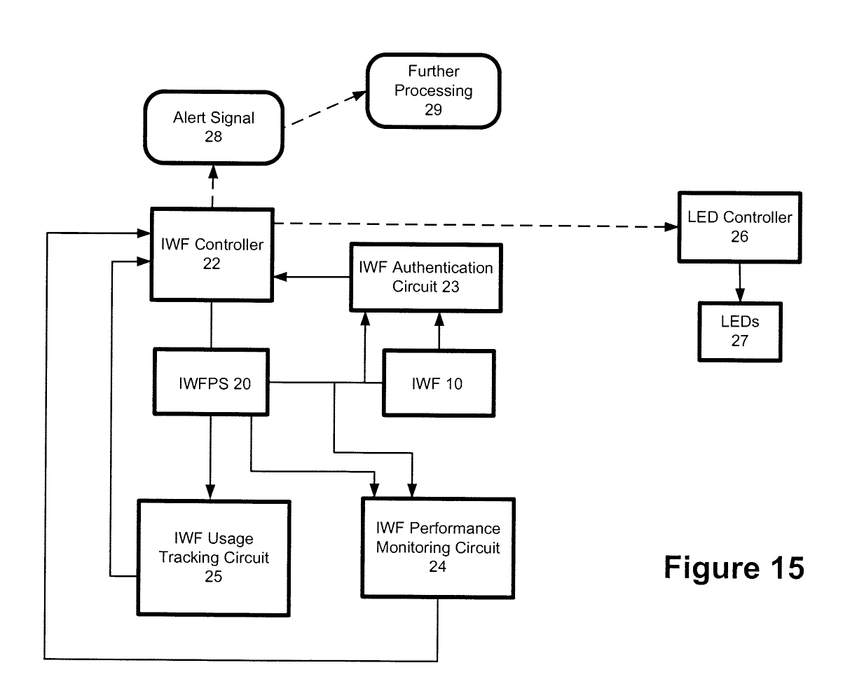

Various embodiments and processes performed by the IWF controller 22 and additional circuits are now described with reference to FIGS. 15, 16, and 17. By making ion wind fans used to thermally manage consumer electronics devices replicable, there will be a market for replacement ion wind fans. In one embodiment of the present invention, the consumer electronic device is configured to only accept authentic original equipment manufacturer “OEM” ion wind fans, or ion wind fans manufactured only by authorized manufacturers.

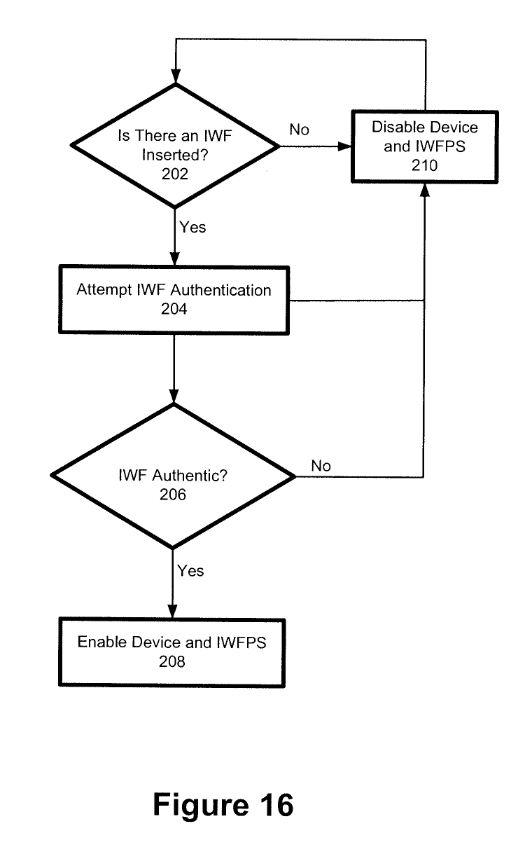

In such an embodiment, the consumer electronics device includes an ion wind fan (“IWF”) authentication circuit 23. The IWF authentication circuit can receive signals from the ion wind fan 10, the IWF power supply 20, or both to determine whether the ion wind fan inserted into the device by a user is an authorized replacement fan. This determination is then communicated to the IWF controller 22 for further processing. Several embodiments of the authentication process are now described with further reference to FIG. 16.

In block 202, a determination is made as to whether an ion wind fan is inserted into the device. In one embodiment, this determination can be made by the IWF authentication circuit 23, or by the power supply 20. For example, a brief test voltage can be provided across the contacts for the ion wind fan to see if any current is generated. In other embodiments, pressure switches, RFID tags, or various other techniques can be used to determine whether an ion wind fan 10 has been inserted into the device and is non-permanently electrically coupled to the IWF power supply 20.

In one embodiment, if no ion wind fan is detected, then, in block 210, the fan controller can disable the IWFPS 20, the entire electronics device (either by accessing a disable switch, or by sending an alert signal to the main central processor), or both. In another embodiment, the consumer electronics device is still allowed to operate when no ion wind fan is inserted, but in a low-power “fan-less” state. For example, in the case of an LED light bulb, if no ion wind fan is inserted, the bulb is lit less dim by driving the LEDs with less power to generate less heat.

In one embodiment, a visual alert is displayed to the user of the consumer electronics device to inform the user that the device is operating in a fan-less state, or that the device is disabled because it is lacking an ion wind fan. Such an alert can be in the form of an email or text message, a display on a screen (for devices that have them, such as computers or smart phones), or it can be flashes of light in the case of LED light bulbs (although LED light bulbs equipped with communications capabilities can also message in other ways described above).

If in block 202 it is determined that an ion wind fan is electrically coupled to the power supply 20, then, in block 204 the authentication circuit attempts to authenticate the ion wind fan. Authentication can be done in various ways. For example, in one embodiment, authentic ion wind fans include an RFID chip bearing an authorized code, and the authentication circuit can include an RFID reader that scans for the code. If no code is detected, or the code is not on the authenticated list, the ion wind fan is not authentic. For additional security, the code may be encrypted using some public key cryptography system, or according to a secret encryption scheme.

In another embodiment, authentic fans can be designed to display a peculiar electrical property upon turn-on or even during operation of the ion wind fan. Such a unique electrical signal can then be detected by the authentication circuit 23 either the high side of the ion wind fan, the low side of the ion wind fan, or across the emitter and collector electrodes of the ion wind fan.

In block 206, a determination is made as the whether the attempt to authenticate the ion wind fan in block 204 has been successful. If the ion wind fan was successfully authenticated as being made by an authorized manufacturer, then, in block 208, the IWF controller 22 enables the IWF power supply 20. In some embodiment, as discussed above, the IWF controller 22 can also directly or indirectly enable the entire consumer electronics device if fan authentication was successful. If, however, the inserted ion wind fan is not found to be authentic in block 206, then processing continues with the disabling or down-throttling of the device in block 210, as discussed above.

In another aspect of the present invention, since the ion wind fan inside the consumer electronics device is user-replaceable, some embodiments of the invention provide for user-notification of fan replacement in advance of ion wind fan failure. In one embodiment, the consumer electronics device includes an IWF usage tracking circuit 25 configured to track the elapsed usage of the ion wind fan since installation. The detection of a new ion wind fan resets the usage tracking circuit 25.

The IWF usage tracking circuit 25 can be implemented by simply incrementing a clock whenever a threshold current or voltage is detected across the IWF power supply 20. In other embodiments, the usage is weighted by fan power, so that lower-power ion wind fan usage increments the usage clock slower than higher-power fan usage. The weighing can be done according to various weighting formulas.

In one embodiment, the consumer electronics device also includes an IWF performance monitoring circuit 24. The performance monitoring circuit 24 can be implemented in various ways to monitor a variety of performance metrics. For example, in one embodiment, the IWF performance monitoring circuit 24 measures the current and voltage across the ion wind fan and evaluates these values to determine the condition and performance of the ion wind fan. For example, if an ion wind fan suddenly uses a higher voltage to generate the same power as previously, this can be a sign of fan aging.

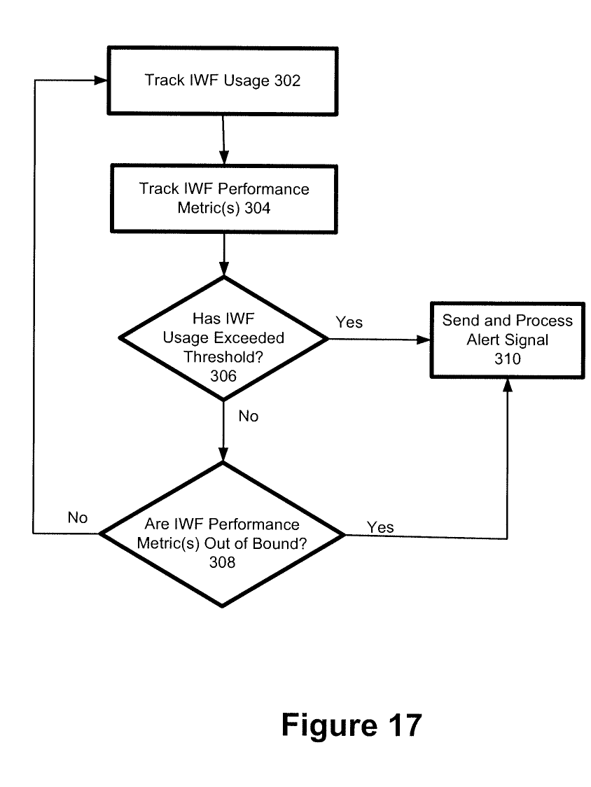

In another embodiment, instead of—or in addition to—electrical measurements, the IWF performance monitoring circuit 24 can measure the airflow generated by the ion wind fan, such as the velocity, volume, flow rate, or pressure of the airflow. In yet other embodiments, the thermal properties of the heat source or the heat sink can be monitored, and a rise in temperature can be correlated with decreased ion wind fan performance. Various processing associated with the IWF performance monitoring circuit is now described with reference to FIG. 17.

In block 302, the usage of the ion wind fan is tracked by the IWF usage tracking circuit 25 as described above. In block 304, one or more performance metrics of the ion wind fan are tracked by the IWF performance monitoring circuit as described above. These tracking processes are generally not sequential and can take place in parallel or simultaneously.

In block 306, a determination is made as to whether the IWF usage threshold has been exceeded. As explained above, the usage threshold can be a measure of on-time, a power-weighted measure of on-time, or other such measure of ion wind fan usage. For example, the usage threshold can be 15,000 hr at 1 W power, or the weighted equivalent (e.g. 30,000 hr at 0.5 W power; although the weights need not be linear as in this example).

If the IWF usage threshold is determined to be exceeded in block 306, then, in block 310, the IWF controller 22 sends an alert signal or message to that effect for further processing. The actions taken by the consumer electronics device in response to the alert signal in block 310 depends—in part—of the type of consumer electronics device being thermally managed using the ion wind fan.

For example, in one embodiment where the consumer electronics device is an LED light bulb and with continued reference to FIG. 15, the device will include an LED controller 26 that controls the illuminating power LEDs 27 (the LED power supply is not shown). In such an embodiment, the IWF controller 22, in response to detecting the ion wind fan exceeding the IWF usage threshold, can signal this determination to the LED controller 26. In one embodiment, in response to such a signal, the LED controller 26 can cause the LEDs 27 to flash periodically, according to some specific pattern, change color, or use some other visual method to signal to the user that the ion wind fan inside of the LED bulb is due for replacement.

In other embodiments, if the consumer electronics device has communications capabilities, these can be used to message the user. For example, a projection device can display a “Please Replace Your Ion Wind Fan” message on power-up. A computing device, or smart device (phone, TV, storage device) can use an email message, an SMS message, a voicemail message, a tweet, or any other messaging technology to alert the user to replace the ion wind fan.

With continued reference to FIG. 17, if in block 306, it is determined that the IWF usage threshold has not been exceeded, then, in block 308, a determination is made as to whether any of the IWF performance metrics measured by the IWF performance monitoring circuit—as discussed above—are out of normal or acceptable bounds. If any performance metrics (or some combination of performance metrics) is/are out of normal range, processing continues at block 310 with the sending of the alert signal for further processing as discussed above. If all—or a sufficient number—or performance metrics are found to be in compliance in block 308, then processing continues at block 302, as discussed above.

In the descriptions above, various functional modules are given descriptive names, such as “IWF authentication circuit,” “IWF controller,” “ion wind fan power supply,” and other such modules and circuits. The functionality of these modules can be implemented in software, firmware, hardware, or a combination of the above. Such modules and circuits can be implemented as separate modules or as various combinations of circuits, processors, and controllers. None of the specific modules or terms—including “power supply” or “ion wind fan”—imply or describe a physical enclosure or separation of the module or component from other system components.

Furthermore, descriptive names such as “emitter electrode,” “collector electrode,” and “isolator,” are merely descriptive and can be implemented in a variety of ways. For example, the “collector electrode,” can be implemented as one piece of metallic structure (as shown in the FIG. 2A, for example), but it can also be made of multiple members spaced apart, and connected by wires or other electrical connections to the same voltage potential, such as ground.

Similarly, the isolator can be the substantially frame-like component shown in FIG. 2A, but it can have various shapes. The electrodes and the isolator are not limited to any particular material; however, the isolator will generally be made of a dielectric material, such as plastic, ceramic, and other known dielectrics. Thus in one embodiment, any of the collector electrodes discussed herein can be substituted for the collector electrode 32 of FIG. 2A to create an ion wind fan according to an embodiment of the present invention. In other embodiments, other isolator designs can be used, as long as it establishes substantially the same spatial relationships between the electrodes.

Furthermore, various spatial terms, such as “above,” or “right,” “next to” are used merely to describe the Figures and for clarity. They are not intended to limit any of the various embodiments of the present invention. The embodiment of the present invention are applicable to any consumer electronics device, and not only the specific electronics devices shown as examples.

1. A consumer electronics device comprising:
a heat source;
a heat sink thermally coupled to the heat source;
a power supply configured to provide a voltage sufficient to power an ion wind fan;
an ion wind fan electrically coupled to the power supply using a non-permanent electrical connector; and
a retention mechanism to removably retain the ion wind fan inside the consumer electronics device so that the ion wind fan provides forced convection to the heat sink when connected to the power supply using the non-permanent electrical connector.

2. The consumer electronics device of claim 1, wherein the non-permanent electrical connector comprises one or more spring contacts.

3. The consumer electronics device of claim 2, wherein the one or more spring contacts comprise a first spring electrode being integrally formed with a collector electrode of the ion wind fan, the first spring electrode protruding from the ion wind fan, wherein the first spring electrode contacts a first electrical contact connected to the low side of the power supply when the ion wind fan is retained by the retention mechanism.

4. The consumer electronics device of claim 3, wherein the one or more spring contacts comprise a second spring electrode being integrally formed with an emitter bus plate used to power one or more emitter electrodes of the ion wind fan, the second spring electrode protruding from the ion wind fan, wherein the second spring electrode contacts a second electrical contact connected to the high side of the power supply when the ion wind fan is retained by the retention mechanism.

5. The consumer electronics device of claim 2, wherein the ion wind fan comprises a collector electrode and a first contact pad electrically coupled to the collector electrode, wherein the one or more spring contacts comprise a first leaf spring electrode electrically coupled to the low side of the power supply, wherein the first leaf spring electrode contacts the first contact pad when the ion wind fan is retained by the retention mechanism.

6. The consumer electronics device of claim 5, wherein the ion wind fan comprises a plurality of emitter electrodes coupled to an emitter bus plate, and a second contact pad electrically coupled to the emitter base plate, wherein the one or more spring contacts comprise a second leaf spring electrode electrically coupled to the high side of the power supply, wherein the second leaf spring electrode contacts the second contact pad when the ion wind fan is retained by the retention mechanism.

7. The consumer electronics device of claim 1, wherein the retention mechanism comprises a tool-less latch mechanism.

8. The consumer electronics device of claim 1, further comprising a fan cartridge having one or more air intake openings and one or more air exhaust openings, wherein the ion wind fan is located inside the fan cartridge and the retention mechanism retains and locates the fan cartridge to the consumer electronics device.

9. The consumer electronics device of claim 1, further comprising a fan controller connected to the power supply, wherein the fan controller receives usage data for the ion wind fan and is configured to generate a signal indicating that the ion wind fan should be replaced based on the usage data.

10. The consumer electronics device of claim 1, further comprising a fan controller connected to the power supply, wherein the controller is configured to authenticate that the ion wind fan was manufactured by an authorized manufacturer.

11. The consumer electronics device of claim 10, wherein the fan controller sends a signal to disable the consumer electronics device in response to a failure to authenticate the ion wind fan.

12. A method comprising:
monitoring, by an ion wind fan (“IWF”) performance monitoring circuit, one or more performance metrics of an ion wind fan, the ion wind fan being used for thermal management of a consumer electronics device; and
generating an alert for a user of the consumer electronics device to instruct the user to replace the ion wind fan using in response to one or more of the performance metrics being outside of a predetermined range.

13. The method of claim 12, wherein the one or more performance metrics comprise a current-voltage (IV) range.

14. The method of claim 12, wherein the one or more performance metrics comprise a current-voltage (IV) shift.

15. The method of claim 12, further comprising collecting, by an IWF usage circuit, usage data for the ion wind fan, and generating an alert for the user of the consumer electronics device to instruct the user to replace the ion wind fan using in response to the usage of the ion wind fan exceeding a predetermined threshold.

16. The method of claim 15, wherein the usage data comprises a total on time weighted by the power level over time of the ion wind fan.

17. The method of claim 12, further comprising authenticating, using an IWF authentication circuit, that the ion wind fan was manufactured by an authorized manufacturer.

18. A solid-state light bulb comprising:
a solid-state light module comprising one or more solid-state lighting devices;
a heat sink comprising a heat spreader having a first surface thermally coupled to the solid-state light module, and a plurality of fins extending from a second surface of the heat spreader;
a fan housing having a plurality of air-passage openings, wherein the fins are situated primarily in the fan housing;
an electronics housing;
an ion wind fan power supply located inside the electronics housing;
an lighting power supply electrically coupled to the solid-state light module located inside the electronics housing;
a fan cartridge removably attached to the fan housing, the fan cartridge having a plurality of air-passage openings; and
an ion wind fan attached to the fan cartridge, the ion wind fan having a non- permanent electrical contact to temporarily electrically couple the ion wind fan to the ion wind fan power supply.

19. The solid-state light bulb of claim 18, wherein the ion wind fan generates an airflow between the air-passage openings of the fan housing and the air-passage openings of the fan cartridge, wherein the airflow impinges on the fins of the heat sink.

20. The solid-state light bulb of claim 18, wherein the ion wind fan is attached to the fan cartridge in a manner that located one or more emitter electrodes of the ion wind fan inside of the fan cartridge.
